(19) United States
(12) Patent Application Publication
(10) Pub. No.: US 2013/0313720 A1
(43) Pub. Date: Nov. 28, 2013

(54) PACKAGING SUBSTRATE WITH RELIABLE VIA STRUCTURE

(71) Applicants: Leilei ZHANG, Sunnyvale, CA (US); Zuhair Bokharey, Fremont, CA (US)

(72) Inventors: Leilei ZHANG, Sunnyvale, CA (US); Zuhair Bokharey, Fremont, CA (US)

(21) Appl. No.: 13/481,173

(22) Filed: May 25, 2012

(51) Int. Cl. H01L 23/498; H01L 21/768

(52) U.S. Cl. 257/774; 438/667; 257/E23.067; 257/E21.578; 257/E21.585

(57) ABSTRACT

A packaging substrate includes a high reliability via structure that extends through multiple layers of the packaging substrate. The via structure includes an opening formed through multiple layers of the packaging substrate and an electrically conductive layer that is deposited in the opening. The opening is formed in a single material removal process and the conductive layer is formed in a single deposition process. Because the conductive layer is formed in a single deposition process, the conductive layer provides an interface-free conductive path between the multiple layers.

### BACKGROUND OF THE INVENTION

1. Field of the Invention

Embodiments of the present invention relate generally to integrated circuit chip packaging and, more specifically, to a packaging substrate with a reliable via structure.

2. Description of the Related Art

In the packaging of integrated circuit (IC) chips, a semiconductor chip is usually mounted on a packaging substrate to facilitate electrical connection of the chip to a motherboard or other printed circuit board (PCB). In order to provide the high density of electrical connections typical of modern IC chips and expanded wiring layout required for such chips, packaging substrates have advanced from being single-layered boards to multiple-layered structures that include multiple build-up layers formed on a core board. One such packaging substrate is illustrated in FIG. 1.

FIG. 1 is a schematic cross-sectional view of a packaging substrate 100 that includes a core board 101 and multiple build-up layers 102 on each side of core board 101. A plurality of micro-bumps 103 are arrayed on a chip-mounting surface 110 of packaging substrate 100 and a plurality of solder balls 104 are arrayed on a PCB mounting surface 120. An IC chip (not shown) is electrically coupled to packaging substrate 100 with micro-bumps 103, and packaging substrate 100 is electrically coupled to a support structure, such as a PCB (not shown), with solder balls 104. To form electrical interconnects between micro-bumps 103 and solder balls 104, via structures 130 and interconnect lines 140 are formed in core board 101 and build-up layers 102.

Via structures 130 are generally openings formed in core board 101 and build-up layer 102 that are filled with electrically conductive material, such as a plated metal. The formation of each via structure 130 typically involve multiple process steps, each of which must be tightly controlled to ensure proper positioning and geometry of each via structure 130. For example, inadequate control of either material removal or surface cleaning processes can result in via structures 130 with poor positioning and/or dimensions. In some instances, contact between via structures 130 and interconnect lines 140 may occur, which is highly undesirable. In other instances, poorly formed via structures 130 can result in only partial electrical contact with micro-bumps 103 and/or solder balls 104. Consequently, the various processes used to form via structures 130 must be tightly controlled, resulting in a narrow process window and a more difficult manufacturing process.

As shown in FIG. 1, via structures 130 in adjacent layers of packaging substrate 100 are frequently “stacked,” i.e., positioned in contact with each other, to provide a conductive path through multiple layers of packaging substrate 100. Stacked via structure 131 is one such example. Via structures 131A and 131B, which together make up stacked via structure 131, are each formed in a separate series of process steps and, consequently, an interface 135 exists therebetween. Interface 135 is generally susceptible to cracking and other reliability issues due to surface contamination and/or oxidation of via structure 131A prior to the formation of via structure 131B.

As the foregoing illustrates, there is a need in the art for a reliable packaging substrate that is easily manufactured.

### SUMMARY OF THE INVENTION

One embodiment of the present invention sets forth a packaging substrate with a high reliability via structure that is extends through multiple layers of the packaging substrate. Such a via structure does not include stacked vias that are each formed in a single layer of the packaging substrate. Instead, the via structure includes an opening formed through multiple layers of the packaging substrate and an electrically conductive layer that is deposited in the opening. The opening is formed in a single material removal process and the conductive layer is formed in a single deposition process. Because the conductive layer is formed in a single deposition process, the conductive layer provides an interface-free conductive path between the multiple layers.

One advantage of the present invention is that a packaging substrate can be formed with more reliable via structures than stacked via structures currently known in the art, because no interface is present in the via structure at the interface between layers of the packaging substrate. Furthermore, in some embodiments the packaging substrate can also be fabricated in fewer total process steps than a conventional packaging substrate that includes stacked via structures, since each via structure in the stack is formed through a single layer of the packaging substrate.

### BRIEF DESCRIPTION OF THE DRAWINGS

So that the manner in which the above recited features of the present invention can be understood in detail, a more particular description of the invention, briefly summarized above, may be had by reference to embodiments, some of which are illustrated in the appended drawings. It is to be noted, however, that the appended drawings illustrate only typical embodiments of this invention and are therefore not to be considered limiting of its scope, for the invention may admit to other equally effective embodiments.

FIG. 1 is a schematic cross-sectional view of a packaging substrate that includes a core board and multiple build-up layers on each side of the core board;

FIG. 2 is a schematic cross-sectional view of a packaging substrate configured according to one embodiment of the present invention;

FIG. 3 is a schematic cross-sectional view of a packaging substrate configured according to another embodiment of the present invention;

FIG. 4 sets forth a flowchart of method steps for forming a packaging substrate with a high-reliability via structure, according to an embodiment of the invention;

FIG. 5A illustrates a core board of a packaging substrate with build-up layers formed thereon after the completion of one step of the method illustrated in FIG. 4;

FIG. 5B illustrates an opening formed in two or more layers of the packaging substrate after the completion of another step of the method illustrated in FIG. 4;

FIG. 5C illustrates a via structure formed by depositing an electrically conductive material in the opening illustrated in FIG. 5B; and

FIG. 6 illustrates a computing device in which one or more embodiments of the present invention can be implemented.

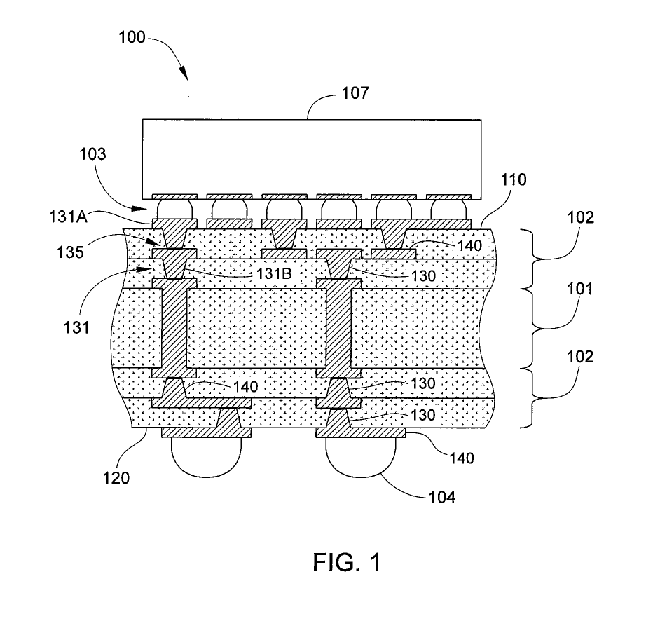

For clarity, identical reference numbers have been used, where applicable, to designate identical elements that are common between figures. It is contemplated that features of one embodiment may be incorporated in other embodiments without further recitation.

### DETAILED DESCRIPTION

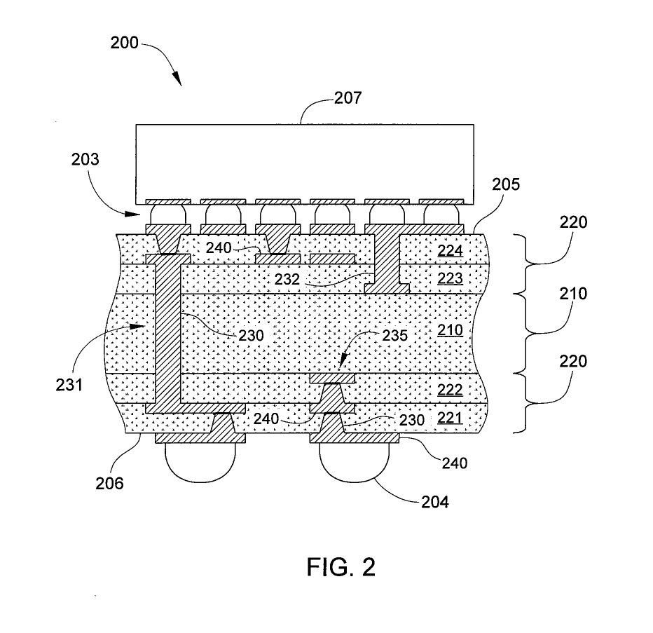

FIG. 2 is a schematic cross-sectional view of a packaging substrate 200 configured according to one embodiment of the present invention. Packaging substrate 200 provides an integrated circuit (IC) chip package with structural rigidity as well as an electrical interface for routing input and output signals and power between one or more IC chips 207 and an underlying support structure, such as a printed circuit board (PCB) (not shown). The one or more IC chips 207 may include any IC chip or die known in the art, such as a central processing unit, a graphics processing unit, a memory chip, and the like.

Packaging substrate 200 includes a core board 210 and multiple build-up layers 220 on each side of core board 210. Packaging substrate 200 also includes via structures 230, which are configured according to embodiments of the invention in build-up layers 220 and core board 210. A plurality of micro-bumps 203 or other chip package electrical connections may be arrayed on a chip-mounting surface 205 of packaging substrate 200, and a plurality of solder balls 204 or other chip package electrical connections may be arrayed on a PCB mounting surface 206. One or more IC chips 207 may be electrically coupled to packaging substrate 200 with micro-bumps 203, and packaging substrate 200 is electrically coupled to the underlying support structure with solder balls 204. To form electrical interconnects between micro-bumps 203 and solder balls 204, via structures 230 and interconnect lines 240 are formed in core board 210 and build-up layers 220.

In the configuration illustrated in FIG. 2, packaging substrate 200 is configured with micro-bumps 203 and solder balls 204 for electrical connections. However, it is noted that packaging substrate 200 may include any technically feasible chip package electrical connection known in the art, such as wire bonding for electrically coupling the one or more IC chips 207 to chip-mounting surface 205, or a pin-grid array (PGA) for electrically coupling packaging substrate 200 to a PCB or other support structure.

Core board 210 includes a rigid and thermally insulating material on which one or more build-up layers 220 are formed. There are a number of suitable materials widely known in the art for manufacturing core board 210 and build-up layers 220 that posses the requisite mechanical strength, electrical properties, and desirably low thermal conductivity. Such materials include FR-2 and FR-4, which are traditional epoxy-based laminates, and the resin-based Bismaleimide-Triazine (BT) from Mitsubishi Gas and Chemical.

Together, via structures 230 and interconnect lines 240 provide electrically conductive paths for power, ground, and/or input/output signals from IC chip 207 to solder balls 204. As shown, one or more of via structures 230 are formed through multiple layers of packaging substrate 200. For example, a via structure 231 is formed through core board 210 and build-up layers 222 and 223. In another example, a via structure 232 is formed through build-up layers 223 and 224. Each of via structures 231 and 232 includes an opening formed in multiple layers of packaging substrate 200 and a conductive material deposited in the opening, such as plated copper. The opening for via structures 231 and 232 is formed in a single material removal process, such as a laser drilling process. Similarly, the conductive material deposited in the opening of either via structure 231 or 232 is deposited in a single deposition process. In this way, an interface-free conductive path is formed between the layers of packaging substrate 200 through which the via structure is formed. For example, via structure 231 provides an interface-free conductive path between build-up layer 221 and build-up layer 224. Similarly, via structure 232 provides an interface-free conductive path between chip-mounting surface 205 and core board 210. It is noted that in some embodiments, as illustrated in FIG. 2, a packaging substrate may include a combination of stacked via structures 235 and via structures that extend through multiple layers of the packaging substrate, such as via structures 231 and 232.

Since the openings for via structures 230 are formed through multiple layers of packaging substrate 200 with a single material removal process and a single deposition process, packaging substrate 200 can be fabricated in fewer total process steps than a conventional packaging substrate. Rather than forming stacked vias, which are, formed in a layer-by-layer procedure, via structures 230 can be formed according to embodiments of the invention after some or all of the layers of packaging substrate have been formed. Because the formation of a via structure generally includes multiple process steps (e.g., dielectric material removal, surface cleaning, and conductive material deposition), formation of via structures 230 in a single process sequence can significantly shorten the manufacturing time of packaging substrate 200.

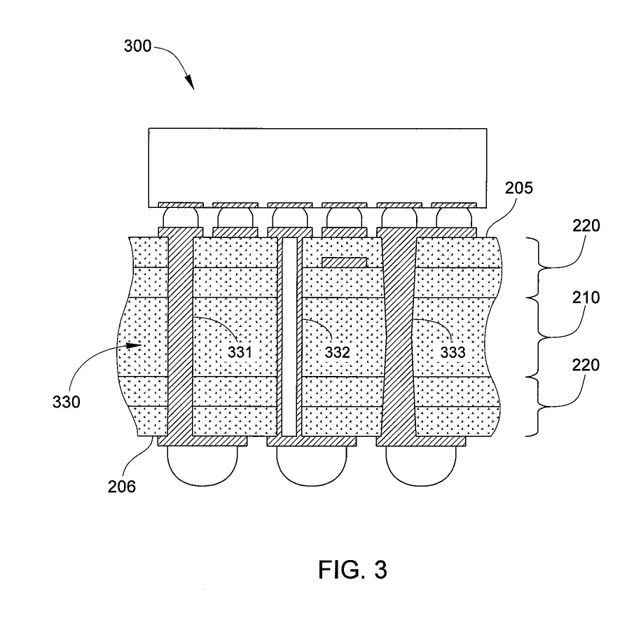

In some embodiments, via structures may be aligned in each layer of a packaging substrate so said via structures can be formed through all layers of the packaging substrate with a single material removal process and a single conductive material deposition process. In such embodiments, manufacturing time of a packaging substrate is significantly reduced, since all via structures can be formed at one time in a single sequence of opening formation, cleaning, and conductive material deposition. FIG. 3 illustrates one such embodiment.

FIG. 3 is a schematic cross-sectional view of a packaging substrate 300 configured according to one embodiment of the present invention. Packaging substrate 300 is substantially similar in configuration and formation to packaging substrate 200 in FIG. 2, except that packaging substrate 300 includes via structures 330 that are formed through all layers of packaging substrate 300. Consequently, packaging substrate 300 provides interface-free conductive paths between each layer of packaging substrate 300.

As shown, packaging substrate 300 includes various configurations of via structures 330, each of which provides an interface-free conductive path between chip-mounting surface 205 and PCB mounting surface 206. Via structure 331 has substantially parallel sides and is filled with electrically conductive material, such as a plated metal. Via structure 332 has substantially parallel sides and includes an electrically conductive material formed on interior surfaces of an opening through all layers of packaging substrate 300. Unlike via structure 331, via structure 332 has a hollow configuration rather than being substantially filled with a conductive material. Generally, the design rules for modern packaging substrates preclude hollow via structures, but for via structures having larger geometries, the hollow configuration of via structure 332 may be desirable. Via structure 333 has tapered sides and is substantially filled with electrically conductive material, such as a plated metal. The tapered configuration of via structure 333 facilitates the complete and void-free deposition of electrically conductive material in higher aspect ratio via structures, i.e., via structures having a relatively narrow opening diameter relative to via structure length. The tapered via structure 333 is generally more desirable for via structures that are formed through all layers of a packaging substrate.

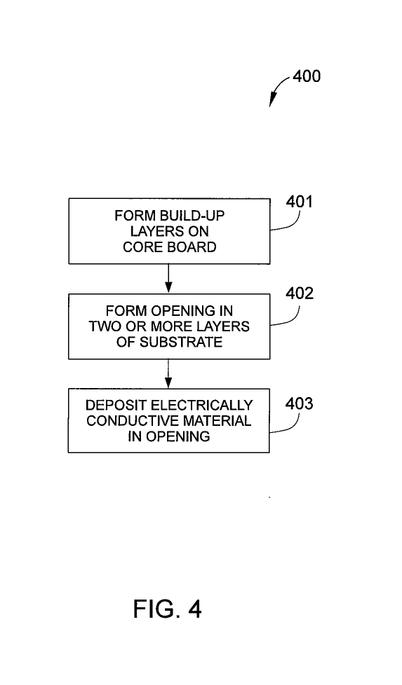

FIG. 4 sets forth a flowchart of method steps for forming a packaging substrate with a high-reliability via structure, according to an embodiment of the invention. Although the method steps are described with respect to packaging substrate 300 of FIG. 3, persons skilled in the art will understand that performing the method steps, in any order, to form any other packaging substrate is within the scope of the invention.

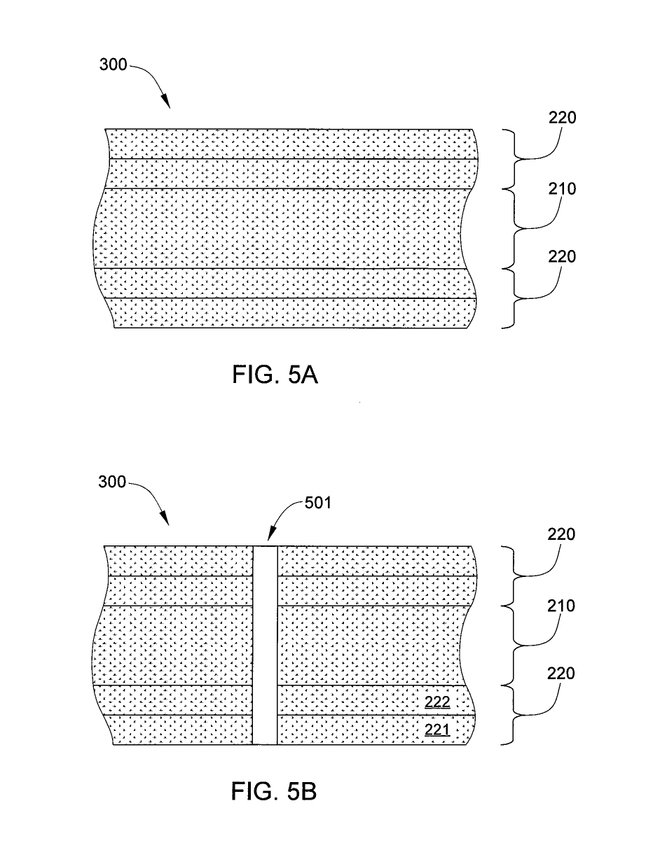

As shown, method 400 begins at step 401, where one or more build-up layers 220 are formed on core board 210. FIG. 5A illustrates core board 210 with build-up layers 220 formed thereon after the completion of step 401.

In step 402, an opening 501 is formed in two or more layers of the packaging substrate, as shown in FIG. 5B. Opening 501 may be formed by any technically feasible material removal process, including laser drilling, mechanical drilling, masking and etching, and the like. For state-of-the-art packaging substrates, laser drilling is typically required to meet the dimensional requirements for opening 501. In the configuration illustrated in FIG. 5B, opening 501 extends through all layers of the packaging substrate. In other embodiments, opening 501 may extend through selected layers of the packaging substrate, e.g., build-up layers 221 and 222.

In step 403, via structure 331 is formed by depositing an electrically conductive material 502 in opening 501, as shown in FIG. 5C. In some embodiments, an electroplating or an electroless plating process is used to deposit electrically conductive material 502 in opening 501. Any other technically feasible process or combination of processes may also be used to deposit electrically conductive material 502, such as metal vapor deposition, sputter deposition, chemical vapor deposition, and the like. Because electrically conductive material 502 is deposited in a single deposition process, no interface is present between the various layers of packaging substrate 300. Consequently, via structure 331 is not susceptible to cracking during use and may also have reduced electrical resistance.

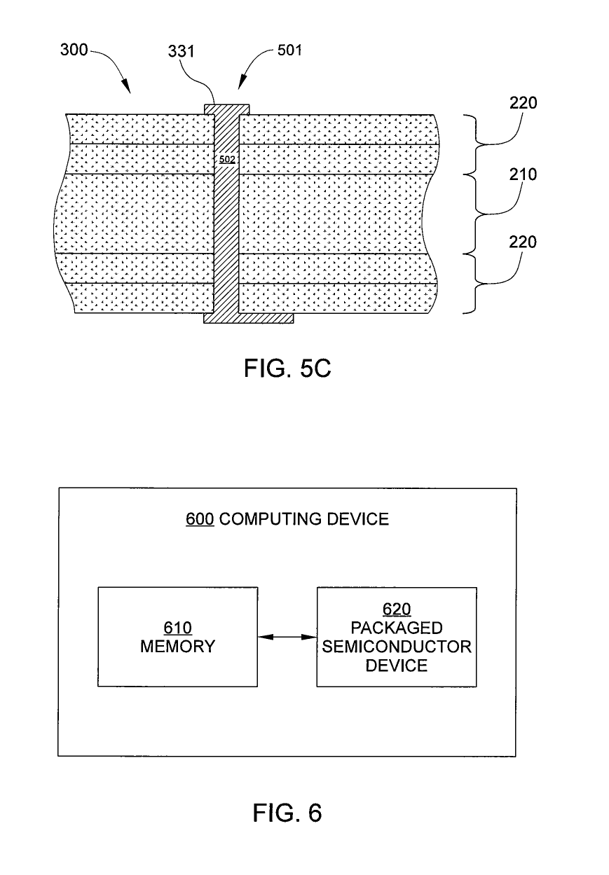

FIG. 6 illustrates a computing device in which one or more embodiments of the present invention can be implemented. Specifically, FIG. 6 is a block diagram of a computer system 600 with a packaged semiconductor device 620 configured according to an embodiment of the present invention. As shown, computer system 600 includes a memory 610 and a packaged semiconductor device 620 that is coupled to memory 610. Computer system 600 may be a desktop computer, a laptop computer, a smartphone, a digital tablet, a personal digital assistant, or other technically feasible computing device. Memory 610 may include volatile, non-volatile, and/or removable memory elements, such as random access memory (RAM), read-only memory (ROM), a magnetic or optical hard disk drive, a flash memory drive, and the like. Packaged semiconductor device 620 includes a semiconductor device, such as IC chip 207 in FIG. 2, that is mounted to a packaging substrate substantially similar in organization and operation to packaging substrates 200 or 300 described above.

In sum, embodiments of the invention set forth a semiconductor packaging substrate with a high reliability via structure that extends through multiple layers of the packaging substrate. Because the via structure is formed in a single material removal process and a single electrically conductive material deposition process, the via structure advantageously provides an interface-free conductive path between multiple layers of the packaging substrate. An additional advantage of such embodiments is that the formation of the via structure through multiple layers of the packaging substrate can significantly reduce the time required to manufacture the packaging substrate.

While the foregoing is directed to embodiments of the present invention, other and further embodiments of the invention may be devised without departing from the basic scope thereof, and the scope thereof is determined by the claims that follow.

We claim:

1. A packaging substrate comprising:
a first layer that includes a first opening;
a second layer that is formed on the first layer and includes a second opening; and
a via structure comprising an electrically conductive layer deposited in the first opening and in the second opening, wherein the electrically conductive layer provides an interface-free electrically conductive path between the first layer and the second layer,
wherein the first opening and the second opening are formed by a single material removal process.

2. The packaging substrate of claim 1, wherein the first layer comprises a core board and the second layer comprises a build-up layer.

3. The packaging substrate of claim 1, wherein the first layer comprises a first build-up layer and the second layer comprises a second build-up layer.

4. The packaging substrate of claim 1, wherein each layer of the packaging substrate includes an opening, the electrically conductive layer is deposited in the opening of each layer, and the opening of each layer is formed by the single material removal process.

5. The packaging substrate of claim 4, wherein the conductive layer provides an interface-free conductive path between each layer of the packaging substrate.

6. The packaging substrate of claim 4, wherein the openings of each layer form a tapered opening in the packaging substrate.

7. The packaging substrate of claim 1, wherein the electrically conductive layer is deposited in a single material deposition process.

8. A computing device, comprising:
a memory; and
a packaged semiconductor device coupled to the memory, wherein the packaged semiconductor device comprises:
a first layer that includes a first opening;
a second layer that is formed on the first layer and includes a second opening, and
a via structure comprising an electrically conductive layer deposited in the first opening and in the second opening, wherein the electrically conductive layer provides an interface-free electrically conductive path between the first layer and the second layer,
wherein the first opening and the second opening are formed by a single material removal process.

9. The computing device of claim 8, wherein the first layer comprises a core board and the second layer comprises a build-up layer.

10. The computing device of claim 8, wherein the first layer comprises a first build-up layer and the second layer comprises a second build-up layer.

11. The computing device of claim 8, wherein each layer of the packaged semiconductor includes an opening, the electrically conductive layer is deposited in the opening of each layer, and the opening of each layer is formed by the single material removal process.

12. The computing device of claim 11, wherein the conductive layer provides an interface-free conductive path between each layer of the packaged semiconductor.

13. The computing device of claim 11, wherein the openings of each layer form a tapered opening in the packaged semiconductor.

14. The computing device of claim 8, wherein the electrically conductive layer is deposited in a single material deposition process.

15. A method of forming a packaging substrate, the method comprising:
forming a first layer;
forming a second layer on the first layer;
forming an opening that extends through the first layer and through the second layer using a single material removal process; and
depositing an electrically conductive material in the opening to form an interface-free conductive path between the first layer and the second layer.

16. The method of claim 15, wherein the first layer comprises a core board and the second layer comprises a build-up layer.

17. The method of claim 15, wherein the first layer comprises a first build-up layer and the second layer comprises a second build-up layer.

18. The method of claim 15, wherein depositing an electrically conductive material comprises depositing the electrically conductive layer in a single material deposition process.

19. The method of claim 15, wherein forming an opening comprises forming an opening that extends through every layer of the packaging substrate using the single material removal process.

20. The method of claim 19, wherein forming an opening comprises forming a tapered opening.
